(19) United States
(12) Patent Application Publication
(10) Pub. No.: US 2008/0156521 A1
(43) Pub. Date: Jul. 3, 2008

(54) PRINTED WIRING BOARD, PRINTED CIRCUIT BOARD, AND ELECTRONIC DEVICE

(75) Inventors: Jun Karasawa, Tokyo (JP); Syuji Hiramoto, Kokubunji-shi (JP)

Correspondence Address: PILLSBURY WINTHROP SHAW PITTMAN, LLP, P.O. BOX 10500, MCLEAN, VA, 22102, US

(73) Assignee: KABUSHIKI KAISHA TOSHIBA, Tokyo (JP)

(21) Appl. No.: 11/960,979

(22) Filed: Dec. 20, 2007

(30) Foreign Application Priority Data
Dec. 27, 2006 (JP) 2006-353038

(51) Int. Cl. H05K 1/18; H05K 1/02

(52) U.S. Cl. 174/260; 174/267

(57) ABSTRACT

According to one embodiment, a printed wiring board includes a plurality of pads to which bumps are to be bonded respectively. The pads are each formed with a plurality of conductors, the conductors are separate from each other and correspond to one of the bumps, and the plurality of conductors define a gap therebetween, the gap being capable of receiving part of the one of the bumps.

### CROSS-REFERENCE TO RELATED APPLICATIONS

This application is based upon and claims the benefit of priority from Japanese Patent Application No. 2006-353038, filed Dec. 27, 2006, the entire contents of which are incorporated herein by reference.

### BACKGROUND

1. Field

One embodiment of the invention relates to a printed wiring board with pads to which bumps are to be bonded, a printed circuit board and an electronic device including the printed wiring board.

2. Description of the Related Art

A method for mounting a circuit component on a printed circuit board in which bumps of circuit component are bonded to pads (i.e., electrodes) that are provided on the printed wiring board is frequently used. A BGA (ball grid array) and CSP (chip size package), for example, have been known as semiconductor packages using such bumps. A flip-chip mounting method is known in which a bear chip is directly mounted on the printed wiring board by utilizing such bumps.

Jpn. Pat. Appln. KOKAI Publication No. 2001-298048 discloses a mounting structure using bumps which enhances the reliability of the bonding parts between the bumps and the pads. In the mounting structure, each pad is reverse conic in shape, and a solder biting part is provided on the circumferential surface of the pad. The reliability of the bonding of the bumps and the pads is enhanced in a manner the bumps are bit by the solder biting part.

The printed wiring board, the semiconductor package or the bear chip thermally expands when the ambient temperature varies or the circuit component is heated. In this case, the bonding part between the pad and the bump is repeatedly subject to thermal stress since the thermal expansion coefficient of the pad and that of the bump are different each other, and thermal stress is accumulated therein. In the case where the bonding strength between the bumps and the pads is not so high, there is a danger that the bonding part will be cracked by the stress, therefore it is impossible to maintain a highly reliable bond over a long period of time.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary partially broken perspective view showing an HDD according to a first embodiment of the present invention;

FIG. 2 is an exemplary cross-sectional view showing a printed wiring board according to the first embodiment;

FIG. 3 is an exemplary cross-sectional view showing a portion enclosed by a line F3 in the printed wiring board shown in FIG. 2;

FIG. 4 is an exemplary cross-sectional view taken along line F4-F4 in the printed wiring board shown in FIG. 3;

FIG. 5 is an exemplary cross-sectional view showing a modification of the printed wiring board according to the first embodiment;

FIG. 6 is an exemplary cross-sectional view showing a printed wiring board according to a second embodiment of the invention;

FIG. 7 is an exemplary enlarged cross-sectional view showing a portion enclosed by a line F7 in the printed wiring board shown in FIG. 6;

FIG. 8 is an exemplary cross-sectional view taken along line F8-F8 in the printed wiring board shown in FIG. 7;

FIG. 9 is an exemplary cross-sectional view taken along line F9-F9 in the printed wiring board shown in FIG. 7;

FIG. 10 is an exemplary cross-sectional view showing a printed wiring board according to a third embodiment of the invention;

FIG. 11 is an exemplary cross-sectional view showing a printed wiring board according to a fourth embodiment of the invention;

FIG. 12 is an exemplary cross-sectional view taken along line F12-F12 in the printed wiring board shown in FIG. 11;

FIG. 13 is an exemplary cross-sectional view taken along line F13-F13 in the printed wiring board shown in FIG. 11;

FIG. 14 is an exemplary cross-sectional view showing a modification of the printed wiring board according to the fourth embodiment; and

FIG. 15 is an exemplary cross-sectional view showing a printed wiring board according to a fifth embodiment of the invention.

### DETAILED DESCRIPTION

Various embodiments according to the invention will be described hereinafter with reference to the accompanying drawings. In general, according to one embodiment of the invention, a printed wiring board includes a plurality of pads to which bumps are to be bonded respectively. The pads are each formed with a plurality of conductors, the conductors are separate from each other and correspond to one of said bumps, and the plurality of conductors define a gap therebetween, the gap being capable of receiving part of the one of said bumps.

According to one embodiment of the invention, an electronic device includes a printed circuit board. According to one embodiment of the invention, the printed circuit board includes a circuit component; bumps electrically connected to the circuit component; and a printed wiring board on which the circuit component is mounted, the printed wiring board including a plurality of pads to which the bumps are bonded respectively. The pads are each formed with a plurality of conductors, the conductors are separate from each other and correspond to one of said bumps, and the plurality of conductors define a gap therebetween, the gap receiving part of the one of said bumps.

Embodiments of the present invention will be described with reference to the accompanying drawings applied to an HDD and a printed circuit board used for the HDD.

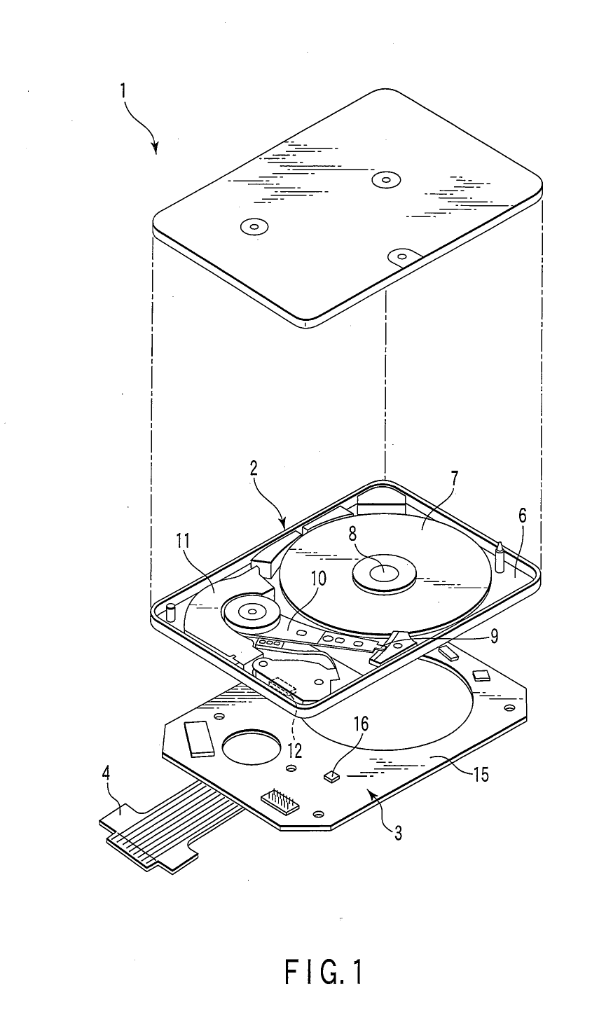

FIG. 1 shows an overall HDD (hard disk drive) 1. The HDD 1 is an example of an electronic device of the present invention. The HDD 1 includes a device body 2, a printed circuit board 3, and an interface board 4. The device body 2 includes a case 6. The case 6 contains a magnetic disc 7, a spindle motor 8, a magnetic head 9, a head actuator 10, a voice coil motor 11, and a signal processor 12. The printed circuit board 3 is a system board for controlling the device body 2 and is electrically connected to the device body 2.

The printed circuit board 3 writes data into and reads data from the magnetic disc 7 as an information recording medium through the operation of the magnetic head 9. In order to provide a functional circuit enabling such a control, the printed circuit board 3 includes a printed wiring board 15 and various types of circuit components mounted thereon. An example of the circuit component is a semiconductor element 16 flip-chip mounted on the printed wiring board 15.

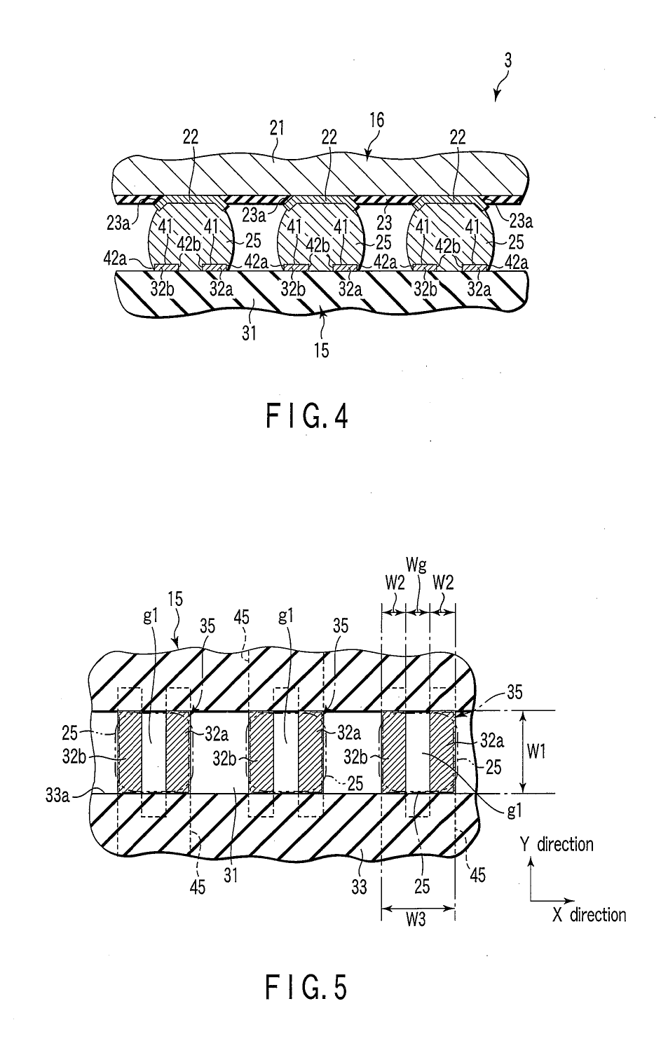

The semiconductor element 16 is called a bear chip. As shown in FIG. 4, the semiconductor element 16 has a chip body 21, electrodes 22 formed on the surface of the chip body 21, and a passivation 23. An example of the electrode 22 is a UBM (under bump metal) having a size of about 100 μm×100 μm. Openings 23a are formed in areas of the passivation 23, which opposed to the electrodes 22, and the electrodes 22 are exposed through the openings 23a to outside the semiconductor element 16. A diameter of the openings 23a is about 90 μm, for example.

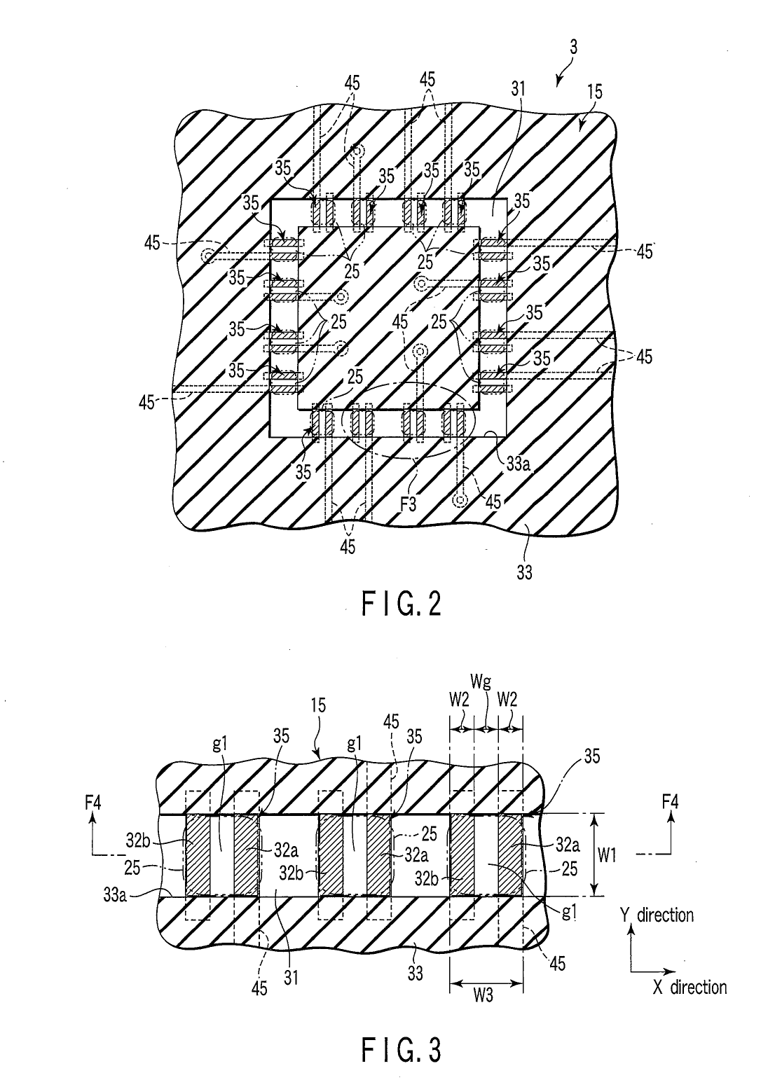

Bumps 25 are supplied to the electrodes 22 of the semiconductor element 16, and electrically connected to the semiconductor element 16. The bumps 25 may be solder balls. The semiconductor element 16 may be a bear IC of the peripheral type in which the electrodes 22 to which the bumps 25 are supplied are disposed on and along the peripheral edge part of the chip body 21 (FIG. 2).

The printed wiring board 15 according to the first embodiment of the present invention will be described in detail with reference to FIGS. 2 to 4.

As shown in FIGS. 3 and 4, the printed wiring board 15 includes an insulating layer 31, first and second plural conductors 32a and 32b formed on the insulating layer 31, and a solder resist 33 as the outermost layer of the printed wiring board 15. The solder resist 33 forms an example of a protective film of the invention.

As shown in FIG. 3, the first and second conductors 32a and 32b are respectively provided at the positions corresponding to the bumps 25. The solder resist 33 includes a frame-like opening 33a which opens the areas corresponding to the bumps 25 altogether. In this embodiment, a draft width W1 (FIG. 3) of the opening 33a is slightly larger than 120 μm. The first and second conductors 32a and 32b extend from the area covered with the solder resist 33 to the inside of the opening 33a. The first and second conductors 32a and 32b, which are located inside the opening 33a, are exposed to outside the printed wiring board 15 through the opening 33a. In other words, the portions of the first and second conductors 32a and 32b exposed through the opening 33a serve as pads 35 of the printed wiring board 15.

The pads 35 which the bumps 25 are to be bonded are each formed with first and second conductors 32a and 32b. The plurality of pads 35 are arranged side by side. The first and second conductors 32a and 32b are separate from each other and correspond to one of said bumps. The opening 33a of the solder resist 33 extends in the direction in which the plurality of pads 35 are arranged (to be referred to as an X direction), and allows the plurality of pads 35 to be collectively exposed to outside the printed wiring board 15. The first and second conductors 32a and 32b extend in parallel with each other, and in the direction vertical to the direction (to be referred to a Y direction) in which the plurality of pads 35 are arranged, and crossing the opening 33a. The first and second conductors 32a and 32b are arranged side by side in the X direction.

As shown in FIG. 3, a line width W2 of each of the first and second conductors 32a and 32b is 40 μm. The first and second conductors 32a and 32b are separate from each other by a gap g1. In other words, the first and second conductors 32a and 32b define a gap therebetween. A width Wg of the gap g1 is 40 μm, for example. Therefore, a width W3 of the pad 35 as viewed in the X direction is 120 μm. The draft width W1 of the opening 33a of the solder resist 33 and the width W3 of the pad 35 define a square of about 120 μm×120 μm of the pad 35.

The first and second conductors 32a and 32b, are symmetrical to each other in the X direction with respect to the central part of the bump 25. The gap g1 between the first and second conductors 32a and 32b corresponds in position to the central part of the bump 25.

The gap g1 is capable of receiving part of the bump 25. As shown in FIGS. 3 and 4, when the bumps 25 are bonded to the pads 35, each bump 25 expands over the entire area of the pad 35 and part of the bump 25 enters the gap g1 between the first and second conductors 32a and 32b. The bumps 25 are bonded to the top faces 41 of the first and second conductors 32a and 32b and also to the side faces 42a and 42b of the first and second conductors 32a and 32b as viewed in the line width direction. Thus, the bump 25 is bonded to the side faces 42b of the pad 35, which face the gap g1 as well as the side faces 42a as the outer side of the pad 35. In the present embodiment, the bumps 25 are each bonded to both the side faces 42a and 42b. It suffices for the invention that the bumps 25 are each bonded at least to the side face 42b facing the gap g1.

As shown in FIG. 3, wirings 45 are provided on the printed wiring board. One end of the first conductor 32a extends to the area covered with the solder resist 33 and is electrically connected to a wiring 45. When viewing from another view point, it may be said that a portion of the tip end of the wiring including the conductor 32a, which is exposed through the opening 33a of the solder resist 33, forms part of the pad 35. The wirings 45, which form parts of a circuit provided on the printed wiring board 15, are used for the signal and power transmission to the semiconductor element 16, for earthing and the like. Signals derived from the semiconductor element 16 are transmitted to the wirings 45 through the first conductors 32a.

Both ends of the second conductor 32b slightly extend to the area covered with the solder resist 33, and are electrically connected to none of the wirings 45 of the printed wiring board 15. The second conductors 32b is void pad (so called dummy pad) for stabilizing the bonding state of the bumps 25. In the specification, “void pad” means a pad which is provided not for the purpose of signal transmission and does not function as part of the power supply line.

An example of a method of manufacturing the printed circuit board 3 will be described hereunder.

To manufacture the printed wiring board 15, a multi-layered plate is arranged in which an inner layer core material having, for example, an inner layer pattern formed thereon and the pre-preg are layered. An outer layer pattern including the first and second conductors 32a and 32b and the wirings 45 is formed on a surface of the multi-layered plate. The first and second conductors 32a and 32b and the wirings 45 may be formed by any suitable process, such as a subtractive process or additive process.

A solder resist 33 is further formed on the outer layer pattern. The solder resist 33 is subjected to the patterning including the exposure and development processes to form an opening 33a. The first and second conductors 32a and 32b are exposed to the exterior of the printed wiring board 15 and used as pads 35. The exposed pads 35 are plated with Ni/Au or Sn, if necessary. Solder paste is screen printed on the pads 35, whenever necessary.

The semiconductor element 16 is mounted by the so-called C4 mounting method. Specifically, bumps 25 have been supplied to the electrodes 22 of the semiconductor element 16. The semiconductor element 16 provided with the bumps 25 is mounted on the printed wiring board 15 arranged as mentioned above. More specifically, the printed wiring board 15 is put in a reflow furnace, in a state that the bumps 25 are placed on the pads 35, whereby a reflow process is executed. Through the reflow process, the bumps 25, which are solder balls in the present embodiment, are melted to be fused to the pads 35. In the embodiment, the molten bumps 25 flow into the gaps g1 each between the first and second conductors 32a and 32b and are fused to the side faces 42b of the first and second conductors 32a and 32b. That is, the gap g1 receives part of the bump 25. After the semiconductor element 16 is mounted on the printed wiring board 15, a buffering material such as an underfill material is supplied to between the semiconductor element 16 and the printed wiring board 15 to reinforce the bonding parts.

In the printed wiring board 15 thus constructed, the bonding strength between the bumps 25 and the pads 35 is increased. When the pads 35 are each formed with the first and second conductors 32a and 32b, which are spaced from each other by the gap g1, the bump 25 partially enters the gap g1. Part of the bump 25 having entered the gap g1 is bonded to the side faces 42b of the first and second conductors 32a and 32b.

When the bumps 25 are bonded to the side faces 42b in addition to the top faces 41 of the pads 35 to set up a three-dimensional bonding state, the bonding strength between the bumps 25 and the pads 35 is increased. When the pads 35 of the present embodiment are used, the areas of the side faces of the pads 35 to which the bumps 25 are to be bonded are larger than those in the case where the pads are each formed with a single conductor. When the areas of the side faces of the pads 35 to which the bumps 25 are to be bonded are large, the bonding strength between the bumps 25 and the pads 35 is increased.

In the printed circuit board 3 and the HDD 1 with the printed wiring board 15, the bonding strength between the bumps 25 and the pads 35 is increased, thereby providing the printed circuit board 3 and the HDD 1, the reliability of the bonding parts of which is ensured for a longer period of time. Further, the printed circuit board 3 and the HDD 1, which are improved in impact resistance in a free-fall drop, for example, can be provided.

When at least one of the first and second conductors 32a and 32b is connected to the wiring 45 which functions as part of the circuit, the pads 35 function as pads for signal transmission, power supply or earthing. It is noted that even if the pads 35 are each formed with plural and independent conductors 32a and 32b, the function of the pad 35 is secured.

In other words, even in the case of the void pad in which one of the plural conductors 32a and 32b is connected to none of the wirings, the pad 35 is capable of exhibiting its original function. In the case where one of the plural conductors 32a and 32b forms the void pad, the following advantages are produced when compared to the case where the conductors 32a and 32b are connected to the wiring 45. That is, the wiring pattern is simplified, the cost of manufacture is reduced, and freedom of the board layout design is enhanced.

In the case where the conductors 32a and 32b, which linearly extend in parallel with each other, are used for the plurality of conductors forming the pads 35, the pads 35 may be formed with the wiring pattern simpler than in the case where the conductors are complex in shape. With this feature, the wiring pattern dose not become complex easily.

In designing the opening 33a of the solder resist 33, the draft width W1 must be relatively large for the opening accuracy and its alignment with the pads 35. If the opening 33a of the solder resist 33 extends in the direction in which the plurality of pads 35 are arrayed, and the conductors 32a and 32b are arranged in the direction in which the plurality of pads 35 are arrayed, the width W1 and the width W3 of the pad 35 may be close to each other in dimension. When the aspect ratio of the pad 35 is close to 1, the bumps 25 to be bonded to the pads 35 are each spherical in shape. When the bump 25 is close in shape to the sphere (the widths in the X and Y directions are close to each other in dimension), the endurance of the bonding parts between the bumps 25 and the pads 35 to thermal stress is then increased, and to the strain generated in the bonding parts lessens. Thus, the bonding strength between the bumps 25 and the pads 35 is increased.

Since a silicon portion in the semiconductor element 16 and a synthetic resin portion in the printed wiring board 15 have different thermal expansion coefficients from each other, thermal stress is applied also to the bonding parts between the electrodes 22 and the bumps 25. In this case, when the bump 25 is close in shape to the sphere as in the present embodiment, the endurance of the bonding parts between the electrodes 22 and the bumps 25 to thermal stress is increased to improve the bonding strength in the bonding parts.

The bumps 25 used in flip-chip mounting are usually small in size, and the strength of the bonding parts is not so large. Therefore, when the invention is applied to the pads that are used for flip-chip mounting, the useful effects produced will be remarkable.

A modification of the printed wiring board 15 according to the first embodiment of the invention will be described with reference to FIG. 5. The first and second conductors 32a and 32b extend both to the areas covered with the solder resist 33, and are electrically interconnected to each other in the regions covered with the solder resist 33. In the printed wiring board 15 thus constructed, the second conductor 32b also functions as the conductor for signal transmission for example. Accordingly, the electrical connection between the bumps 25 and the pads 35 is enhanced.

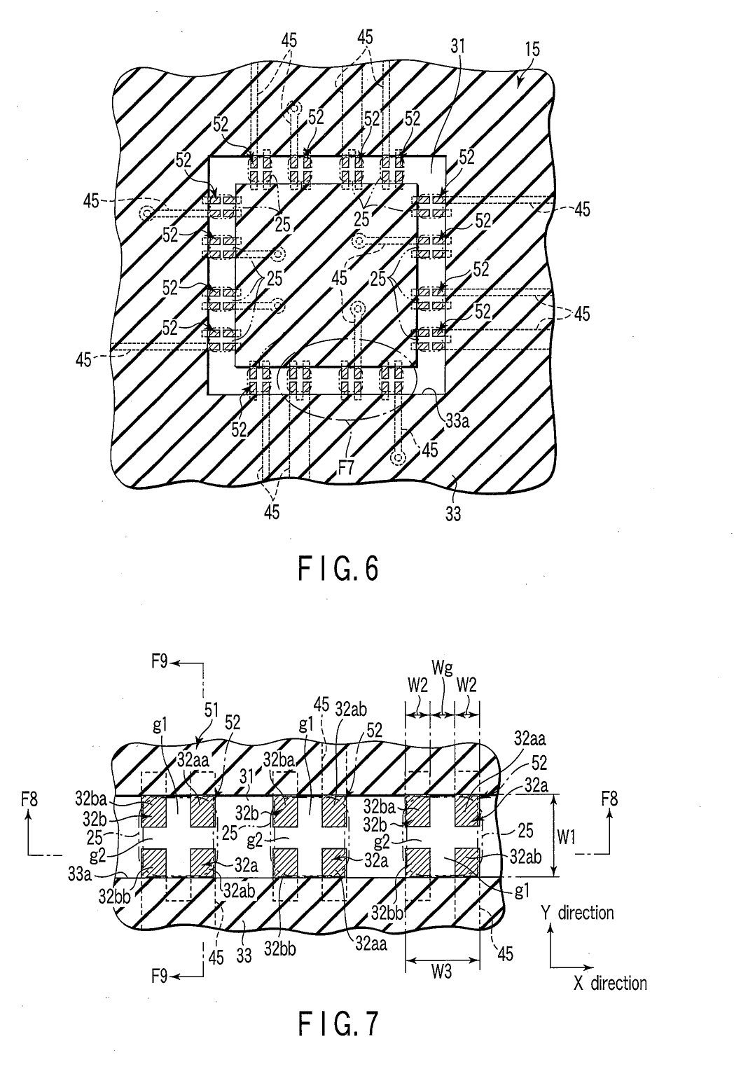

A printed wiring board 51 according to a second embodiment of the present invention will be described with reference to FIGS. 6 to 9. Portions in the second embodiment, which are equal or equivalent to those in the printed wiring board 15 of the first embodiment, will be designated by like reference numerals, and the description thereof will be omitted. As in the first embodiment, the semiconductor element 16 and other various types of circuit components are mounted on the printed wiring board 51 to form a printed circuit board 3 used for the HDD 1.

As shown in FIGS. 6 and 7, pads 52 of the printed wiring board 51 have each first and second conductors 32a and 32b, linearly formed, as in the first embodiment. The first and second conductors 32a and 32b are divided into two parts in their extending direction, and a gap g2 is located therebetween. The first conductor 32a includes a first part 32aa disconnected from the wiring 45 and a second part 32ab electrically connected to the wiring 45. The second conductor 32b is divided into a first part 32ba and a second part 32bb. The second part 32bb of the second conductor 32b may be electrically connected to the wirings 45 or may be a void pad which is not electrically connected to the same.

The pad 52 is quartered by the gap g1 extending in the Y direction and the gap g2 extending in the X direction and is formed with the four separate conductors 32aa, 32ab, 32ba, and 32bb. The shape of each pad 52 is biaxial symmetric in the X and Y directions. When the circuit component 16 is mounted on the printed wiring board 51, part of bump 25 enters the gap g2. The gap g2 is capable of receiving part of the bump 25.

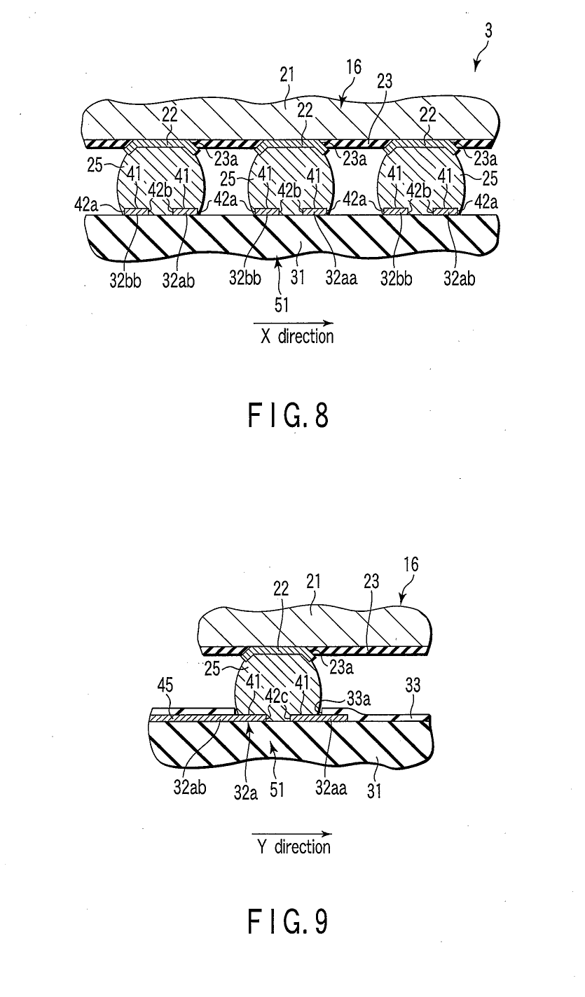

In the printed wiring board 51 thus constructed, the printed circuit board 3 and the HDD 1, the bonding strength of the bumps 25 and the pads 52 can be enhanced. The pads 52 are each formed with the four separate conductors 32aa, 32ab, 32ba, and 32bb, which are spaced by the gaps g1 and g2. As a result, the side faces of the pads 52 to which the bumps 25 are to be bonded become large, so that the bonding strength between the bumps 25 and the pads 52 is increased (FIGS. 8 and 9).

In the case where the pads 52 are each formed with the four separate conductors 32aa, 32ab, 32ba, and 32bb, the bumps 25 are bonded to the side faces 42c of the pads 52, which face the gap g2 (FIG. 9). That is, the gap g2 receives part of the bump 25. Accordingly, the areas of the side faces of the pads 52 to which the bumps 25 are to be bonded are larger than in the case where the pad is formed with two conductors, for example, so that the bonding strength between the bumps 25 and the pads 52 is increased.

In the case where the pads 52 are each divided by the gap g1 extending in the Y direction and the gap g2 extending in the X direction, the shape of each pad 52 is biaxial symmetric in the X and Y directions. Accordingly, the width of the bump 25 as viewed in the X direction is substantially equal to that of the same as viewed in the Y direction. The durability of the bonding parts of the bumps 25 and the pads 52 to thermal stress is therefore enhanced.

With provision of the gap g2 extending in the X direction, when the bumps 25 are bonded to the pads 52, any air present between the conductors 32aa, 32ab, 32ba, and 32bb flows out of the pads 52 by way of the gap g2. Accordingly, there is little chance that voids occur in the bumps 25, leading to increase of the bonding strength between the bumps 25 and the pads 52.

If required, only one of the first and second conductors 32a and 32b may be divided.

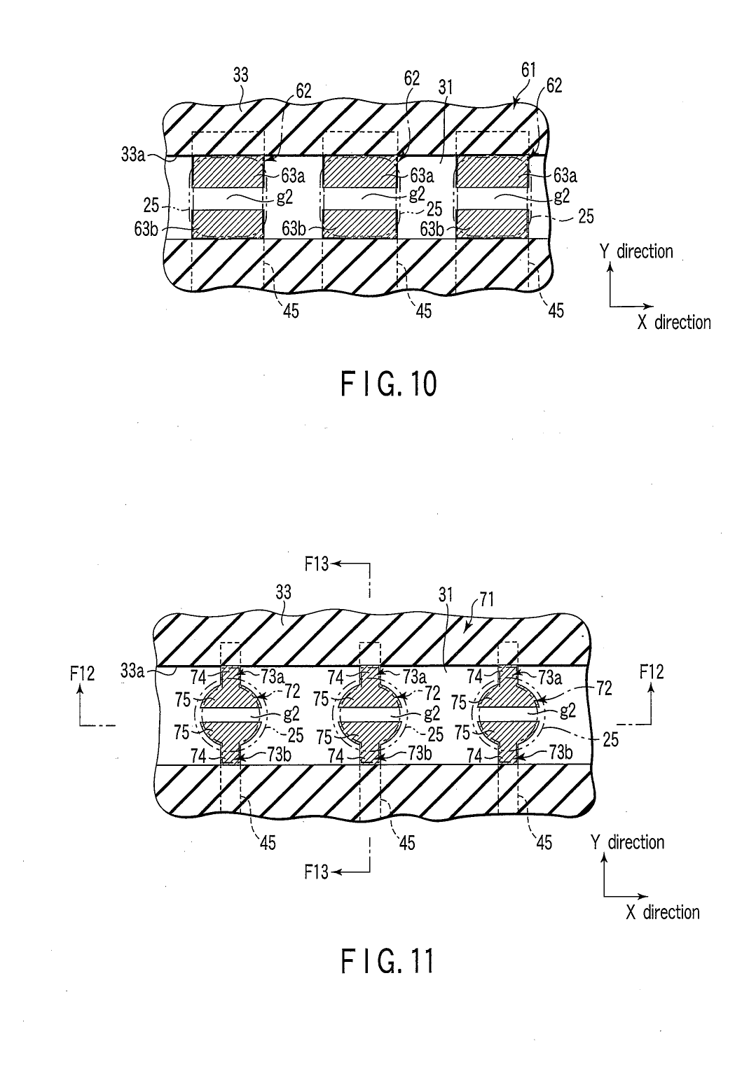

A printed wiring board 61 according to a third embodiment of the present invention will be described with reference to FIG. 10. Portions in the third embodiment, which are equal or equivalent to those in the printed wiring boards 15 and 51 of the first and second embodiments, will be designated by like reference numerals, and a description thereof will be omitted. As in the first embodiment, the semiconductor element 16 and other various types of circuit components are mounted on the printed wiring board 61 to form a printed circuit board 3 used for the HDD 1.

Pads 62 of the printed wiring board 61 have each first and second conductors 63a and 63b. As shown in FIG. 10, the first and second conductors 63a and 63b are arranged side by side in the Y direction. Thus, the pads 62 are each formed with two conductors 63a and 63b, which are separate from each other by a gap g2 extending in the X direction. When the circuit component 16 is mounted on the printed wiring board 61, part of bump 25 enters the gap g2.

In the printed wiring board 61 thus constructed, the printed circuit board 3 and the HDD 1, the bonding strength between the bumps 25 and the pads 62 can be increased. Since the pads 62 are each formed with the first and second plural conductors 63a and 63b, which are separate from each other by the gap g2, the side faces of the pads 62 to which the bumps 25 are to be bonded become large, thereby to increase the bonding strength between the bumps 25 and the pads 62. Since the gap g2 extending in the X direction is provided, there is little chance that voids occur in the bumps 25.

A printed wiring board 71 according to a fourth embodiment of the present invention will be described with reference to FIGS. 11 to 13. Portions in the fourth embodiment, which are equal or equivalent to those in the printed wiring boards 15 and 51 of the first and second embodiments, will be designated by like reference numerals, and a description thereof will be omitted. As in the first embodiment, the semiconductor element 16 and other various types of circuit components are mounted on the printed wiring board 71 to form a printed circuit board 3 used for the HDD 1.

Pads 72 of the printed wiring board 71 each have first and second conductors 73a and 73b. As shown in FIG. 11, the first and second conductors 73a and 73b are arranged side by side in the Y direction. Thus, the pads 72 are each formed with two conductors 73a and 73b, which are separate from each other by a gap g2 extending in the X direction.

The first and second conductors 73a and 73b each have a linear part 74 and an expansion part 75. The linear part 74 linearly extends in the direction in which it crosses the opening 33a. The expansion part 75 is provided at the tip end of the linear part 74 inside the opening 33a, while extending in the width direction of the linear part 74. The first and second conductors 73a and 73b are disposed such that the expansion parts 75 thereof correspond in position to the central parts of the bumps 25. In other words, the pads 72 have each a sphere part corresponding to the bump 25 for example, and the sphere part is divided, by the gap g2 extending in the X direction, into the two conductors 73a and 73b.

In the printed wiring board 71 thus constructed, the printed circuit board 3 and the HDD 1, the bonding strength between the bumps 25 and the pads 72 is increased. Since the pads 72 are each formed with the first and second conductors 73a and 73b, which are separate from each other by the gap g2, the side faces of the pads 72 to which the bumps 25 are to be bonded become large, thereby to increase the bonding strength between the bumps 25 and the pads 72. Since the gap g2 extending in the X direction is provided, there is little chance that voids occur in the bumps 25.

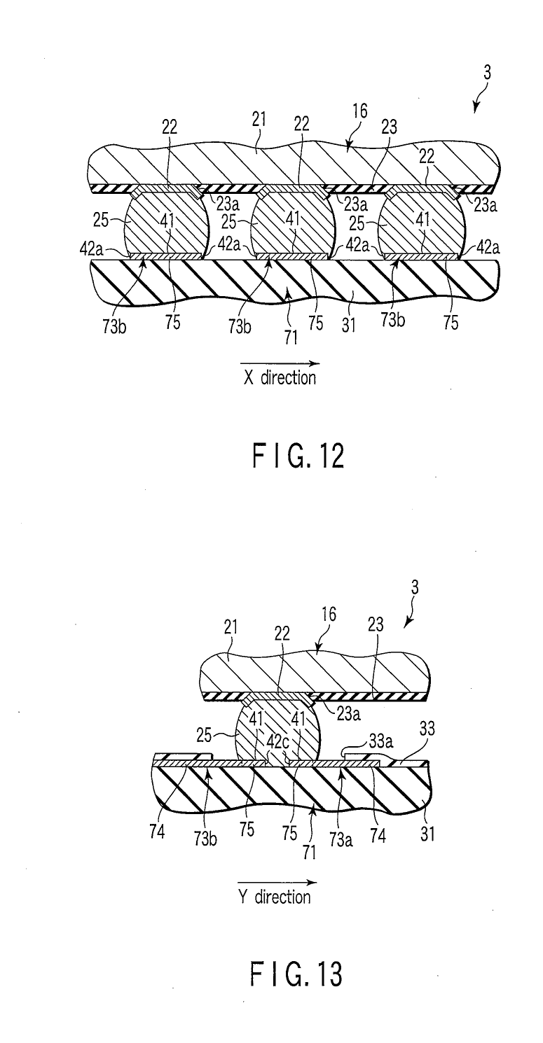

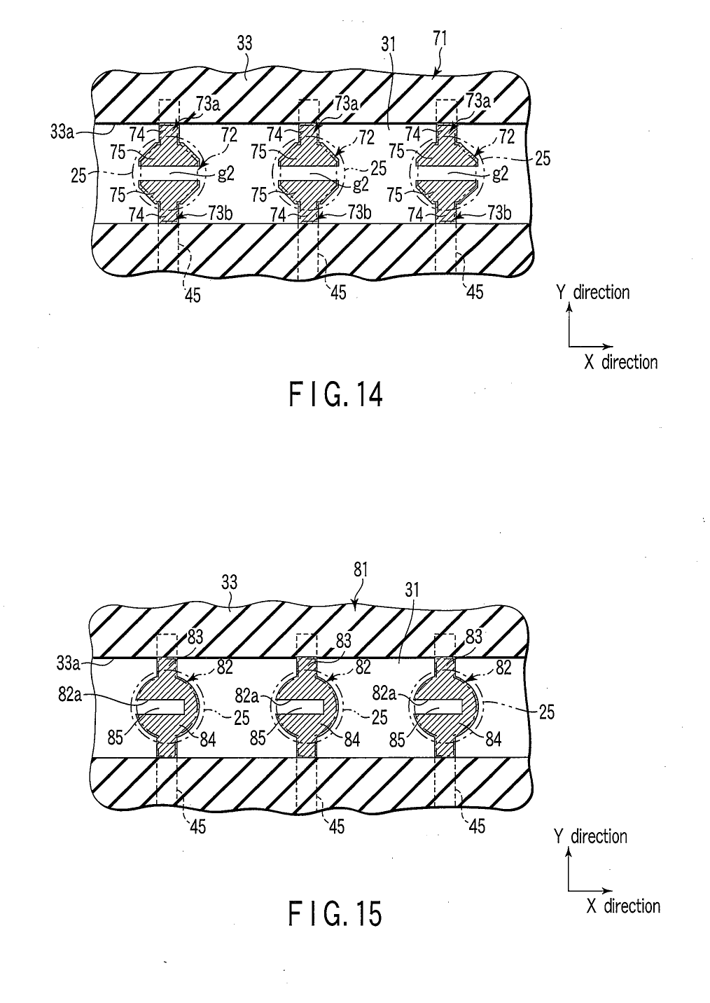

In the case where the first and second conductors 73a and 73b have the expansion part 75, respectively, the widths of the bump 25 in the X and Y directions are easily made substantially equal to each other (FIGS. 12 and 13). When the widths of the bump 25 in the X and Y directions are close to each other in dimension, the endurance of the bonding parts of the bumps 25 and the pads 35 to thermal stress is enhanced. The shape cooperatively formed by the expansion parts 75 of the first and second conductors 73a and 73b is not limited to a sphere, but may be a polygon, as shown in FIG. 14.

A printed wiring board 81 according to a fifth embodiment of the present invention will be described with reference to FIG. 15. Portions in the fifth embodiment, which are equal or equivalent to those in the printed wiring board 15 of the first embodiment, will be designated by like reference numerals, and a description thereof will be omitted. As in the first embodiment, the semiconductor element 16 and other various types of circuit components are mounted on the printed wiring board 81 to form a printed circuit board 3 used for the HDD 1.

Pads 82 of the printed wiring board 81 have each a linear part 83 which linearly extends in the direction of crossing the opening 33a, and an expansion part 84 which extends in the width direction of the linear part 83 inside the opening 33a. The expansion part 84 may be shaped to be a sphere. The expansion part 84 includes a cutout 85 extending in the X direction. The cutout 85 is capable of receiving part of the bump 25.

In the printed wiring board 81 thus constructed, the printed circuit board 3 and the HDD 1, the bonding strength between the bumps 25 and the pads 82 is increased. With provision of the pads 82 having the cutouts 85, part of each bump 25 enters the cutout 85 of each pad 82 to be bonded to a side face 82a of the pad 82 formed by the cutout 85. That is, the cutout 85 receives part of the bump 25. When the areas of the side faces of the pads 82 to which the bumps 25 are to be bonded are made larger, the bonding strength between the bumps 25 and the pads 82 is increased.

While the printed wiring boards 15, 51, 61, 71 and 81 according to the first to fifth embodiments, the printed circuit board 3 and the HDD 1 have been described, it is evident that the present invention is not limited to such embodiments. The constituent elements of the first to fifth embodiments may be appropriately combined. It is evident that the present invention is not limited to the flip-chip mounting pads, but may be applied to the pads to which the bumps for BGA or CSP are to be bonded.

A semiconductor package includes an interpose board and semiconductor elements to be mounted on the board. The present invention may be applied to the pads of the interpose board to which the bumps of the semiconductor elements are to be bonded. The bumps 25 are not limited to the solder balls, as a matter of course. At least one of the conductors 32a, 32b, 32aa, 32ab, 32ba, 32bb, 63a, 63b, 73a, 73b may be electrically connected to the wiring 45. At least one of the conductors 73a, 73b may include the expansion part 75. The opening 23a may expose at least one of pads. And a plurality of the opening 23a may be provided.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A printed wiring board comprising:
a plurality of pads to which bumps are to be bonded respectively,
wherein the pads are each formed with a plurality of conductors, the conductors are separate from each other and correspond to one of said bumps, and
the plurality of conductors define a gap therebetween, the gap being capable of receiving part of the one of said bumps.

2. The printed wiring board according to claim 1, further comprising wirings which are provided on the printed wiring board,
wherein at least one of said conductors is electrically connected to none of the wirings.

3. The printed wiring board according to claim 1, further comprising a wiring which is provided on the printed wiring board and forms part of a circuit,
wherein at least one of said conductors is electrically connected to the wiring.

4. The printed wiring board according to claim 1, further comprising a protective film including an opening formed therein through which the pads are exposed to outside,
wherein at least some of said plurality of conductors are electrically connected to each other in regions covered with the protective film.

5. The printed wiring board according to claim 1, further comprising a protective film including an opening formed therein through which the pads are exposed to outside,
wherein said plurality of conductors extend in the direction of crossing the opening and in parallel with each other.

6. The printed wiring board according to claim 5, wherein the plurality of pads are arranged side by side,
the opening of the protective film extends in the direction in which the plurality of pads are arranged and exposes the pads to outside altogether, and
said plurality of conductors are arranged side by side in the direction in which the plurality of pads are arranged.

7. The printed wiring board according to claim 5, wherein at least one of said plurality of conductors is divided in the extending direction inside the opening.

8. The printed wiring board according to claim 1, further comprising a protective film including an opening formed therein through which the pads are exposed to outside,
wherein the at least one of said conductors includes a linear part extending in the direction of crossing the opening and an expansion part extending in the width direction of the linear part inside the opening.

9. A printed circuit board comprising:
a circuit component;
bumps electrically connected to the circuit component; and
a printed wiring board on which the circuit component is mounted, the printed wiring board including a plurality of pads to which the bumps are bonded respectively,
wherein the pads are each formed with a plurality of conductors, the conductors are separate from each other and correspond to one of said bumps, and
the plurality of conductors define a gap therebetween, the gap receiving part of the one of said bumps.

10. An electronic device comprising, a printed circuit board,
wherein the printed circuit board includes:
a circuit component;
bumps electrically connected to the circuit component; and
a printed wiring board on which the circuit component is mounted, the printed wiring board including a plurality of pads to which the bumps are bonded respectively,
the pads are each formed with a plurality of conductors, the conductors are separate from each other and correspond to one of said bumps, and
the plurality of conductors define a gap therebetween, the gap receiving part of the one of said bumps.
